(19) United States
(12) Patent Application Publication
(10) Pub. No.: US 2025/0006465 A1
(43) Pub. Date: Jan. 2, 2025

(54) Remote Plasma Source and Plasma Processing Chamber Having Same

(71) Applicant: Applied Materials, Inc., Santa Clara, CA (US)

(72) Inventors: Yang YANG, Cupertino, CA (US); Kartik RAMASWAMY, San Jose, CA (US); Fernando SILVEIRA, Livermore, CA (US); Imad YOUSIF, San Jose, CA (US)

(21) Appl. No.: 18/214,745

(22) Filed: Jun. 27, 2023

(51) Int. Cl. H01J 37/32

(52) U.S. Cl. CPC H01J 37/32357; H01J 37/321; H01J 37/3244; H01J 2237/327

(57) ABSTRACT

Methods and apparatus for a point of use remote plasma source are provided. In embodiments, a remote plasma apparatus includes: an enclosure surrounding a cavity; a first conductor surrounding a first portion of the enclosure; a second conductor surrounding a second portion of the enclosure, wherein the first portion of the enclosure and the second portion of the enclosure overlap by an overlap amount, and wherein each of the first conductor and the second conductor are circumferentially discontinuous; a dielectric layer disposed between and separating the first conductor and the second conductor; a gas inlet configured to flow a gas into the cavity; and a gas outlet disposed in a bottom of the enclosure and configured to flow the gas out of the cavity.

### FIELD

Embodiments of the present disclosure generally relate to substrate processing, and in particular, plasma processing of substrates.

### BACKGROUND

Plasma-assisted processing is often used in processing substrates, such as for depositing, etching, or treating material layers on a substrate. In addition to plasma processing, radical etching and other radical processes formed from a remote plasma apparatus are utilized in the processing of substrates. Accordingly, the inventors have provided an improved remote plasma source for processing substrates. The remote plasma source can advantageously be used with a chamber configured for plasma processing.

### SUMMARY

Methods and apparatus for a point of use remote plasma source are provided. In embodiments, a remote plasma apparatus includes: an enclosure surrounding a cavity; a first conductor surrounding a first portion of the enclosure; a second conductor surrounding a second portion of the enclosure, wherein the first portion of the enclosure and the second portion of the enclosure overlap by an overlap amount, and wherein each of the first conductor and the second conductor are circumferentially discontinuous; a dielectric layer disposed between and separating the first conductor and the second conductor; a gas inlet configured to flow a gas into the cavity; and a gas outlet disposed in a bottom of the enclosure and configured to flow the gas out of the cavity.

In some embodiments, a remote plasma apparatus includes: an enclosure comprising a top end, one or more sidewalls forming a cavity within, and an open bottom end engageable with a process chamber, the enclosure having an enclosure circumference and an enclosure height; a first conductor comprising a metal sheet disposed over a first portion of the enclosure in contact with an outer surface of the one or more sidewalls; a dielectric layer comprising a sheet of dielectric material disposed over an outer surface of the first conductor and the outer surface of the one or more sidewalls; a second conductor comprising a metal sheet disposed over a second portion of the enclosure in contact with an outer surface of the dielectric layer, wherein each of the first conductor and the second conductor independently have a conductor length of less than or equal to about 99% of the enclosure circumference and a conductor height of greater than or equal to about 50% of the enclosure height, wherein the first portion of the enclosure and the second portion of the enclosure are different and overlap by an overlap amount, and wherein the first conductor, the second conductor, and the dielectric layer are dimensioned and arranged about the enclosure to have a resonance at an RF frequency within a range of about 400 kHz to 10,000 GHz; a gas inlet comprising a first plurality of inlet conduits dimensioned and arranged to direct a flow of gas into the cavity, and a second plurality of inlet gas conduits dimensioned and arranged to direct the flow of gas into a process chamber to which the remote plasma apparatus is attached to, bypassing the cavity; and a gas outlet disposed in a bottom of the enclosure and configured to flow the gas out of the cavity, wherein the gas outlet includes a gas distribution plate comprising a plurality of holes disposed therethrough.

In some embodiments, a plasma processing chamber includes: a chamber enclosing a processing volume; a substrate support configured to support a substrate in the processing volume during use; a first RF source configured to provide RF energy at a frequency; and a remote plasma apparatus coupled to the chamber and to the first RF source. The remote plasma apparatus can include: an enclosure surrounding a cavity; a first gas inlet configured to flow a gas into the cavity; a gas outlet disposed in a bottom of the enclosure and configured to flow the gas out of the cavity and into the processing volume; a first conductor surrounding a first portion of the enclosure; a dielectric layer disposed over the first conductor; and a second conductor surrounding a second portion of the enclosure, wherein the first portion of the enclosure and the second portion of the enclosure overlap by an overlap amount, and wherein the first conductor, dielectric layer, and the second conductor at least partially form a capacitor having a resonance proximate the frequency to form an electromagnetic field within the enclosure suitable to form radicals from the gas, when disposed within the enclosure.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1A depicts a side cut-away view of a remote plasma apparatus according to embodiments disclosed herein.

FIG. 1B depicts a schematic, cross-sectional top view of a remote plasma apparatus according to embodiments disclosed herein.

FIG. 1C depicts a cross sectional view of a gas distribution plate according to embodiments disclosed herein.

FIG. 1D depicts a cross sectional view of a gas distribution plate according to embodiments disclosed herein.

FIG. 1E depicts a schematic side view of a remote plasma apparatus having a spiral first conductor according to embodiments disclosed herein.

FIG. 2A depicts a perspective view of an enclosure of a remote plasma apparatus according to embodiments disclosed herein.

FIG. 2B depicts a first conductor as a flat sheet according to embodiments disclosed herein.

FIG. 2C depicts the first conductor of FIG. 2B formed into a “C”-shaped first conductor according to embodiments disclosed herein.

FIG. 2D depicts a first conductor as a flat sheet having non-linear edges according to embodiments disclosed herein.

FIG. 3A depicts an exploded view of a remote plasma apparatus according to embodiments disclosed herein.

FIG. 3B depicts a schematic of conductors in combination with a capacitor according to embodiments disclosed herein.

FIG. 4 is a is a block diagram depicting a processing chamber according to embodiments disclosed herein.

FIG. 5 is a block diagram depicting a remote plasma apparatus having various gas inlets into a cavity according to embodiments disclosed herein.

FIGS. 6A-6B depict side cut-away views of a remote plasma apparatus according to embodiments disclosed herein.

FIG. 7 is a block diagram depicting a processing chamber having a plurality of remote plasma apparatus according to embodiments disclosed herein.

FIG. 8 is a flowchart depicting a method of generating plasma according to embodiments disclosed herein.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

As used herein, the terms “on” or “over”, “above,” “below,” and “between” as used herein refer to a relative position of one component (e.g., a layer) with respect to other components. As such, a first component disposed on, over, above or below another component may be directly in contact with the other component or may have one or more intervening components. Moreover, one component disposed between two other components may be directly in contact with the components or may have one or more intervening components. In contrast, a component disposed in contact with another component refers to the two components being in direct contact with each other.

In embodiments, a remote plasma apparatus comprises an enclosure surrounding a cavity; a first conductor surrounding a first portion of the enclosure; a second conductor surrounding a second portion of the enclosure; wherein an area of the first portion and an area of the second portion are each individually less than a total area of the enclosure; wherein the second conductor is separated from the first conductor by a dielectric layer; wherein the first portion of the enclosure and the second portion of the enclosure overlap by an overlap amount; a gas inlet configured to flow a gas into the cavity; and a gas outlet configured to flow the gas out of the cavity. In embodiments, the first portion and the second portion are different.

In embodiments, a remote plasma apparatus comprises an enclosure surrounding a cavity; a first conductor surrounding a first portion of the enclosure; a second conductor surrounding a second portion of the enclosure, wherein the first portion of the enclosure and the second portion of the enclosure overlap by an overlap amount, and wherein each of the first conductor and the second conductor are circumferentially discontinuous; a dielectric layer disposed between and separating the first conductor and the second conductor; a gas inlet configured to flow a gas into the cavity; and a gas outlet disposed in a bottom of the enclosure and configured to flow the gas out of the cavity. In embodiments, the first portion and the second portion are different.

In embodiments, the enclosure comprises a hollow cylinder closed at one end opposite the gas outlet, having an enclosure circumference and a cylinder height such that the cavity is formed within the hollow cylinder; wherein the first conductor and the second conductor are each C-shaped metal sheets, each having a conductor length of less than or equal to about 99% of the enclosure circumference, and a height of greater than or equal to about 50% of the cylinder height. In embodiments, the dielectric is a sheet of dielectric material formed into a cylinder, having a dielectric height greater than or equal to the conductor height of the first conductor.

In embodiments, the first conductor comprises a metal sheet disposed over an outer surface of the enclosure; the dielectric layer comprises a sheet of dielectric material disposed over an outer surface of the first conductor and the outer surface of the enclosure; and the second conductor is a metal sheet disposed over an outer surface of the dielectric layer. In embodiments, the dielectric layer comprises a cylinder of dielectric material disposed over an outer surface of the first conductor and the outer surface of the enclosure.

In embodiments, at least one of the first conductor or the second conductor is a spiral comprising a plurality of turns disposed about the corresponding portion of the enclosure. In embodiments, the first conductor is a spiral comprising a plurality of turns disposed about the first portion of the enclosure.

In embodiments, at least one of the first conductor and the second conductor comprises at least one hole disposed therethrough and/or a non-linear edge, dimensioned and arranged to reduce or eliminate eddy currents induced into the remote plasma apparatus by an external RF source.

In embodiments, the first conductor, the second conductor, and the dielectric layer are dimensioned and arranged about the enclosure to have a resonance at an RF frequency in a range of about 400 KHz to 10,000 GHz. In alternative embodiments, the remote plasma apparatus further comprises one or more capacitors in electrical communication between the first conductor and the second conductor such that the remote plasma apparatus has a resonance at an RF frequency in a range of about 400 kHz to 10,000 GHz. In embodiments, the second conductor is movable with respect to the first conductor to change the overlap amount such that the resonance can be variably controlled. In embodiments where the remote plasma apparatus is used in connection with another RF plasma source for forming and/or delivering plasma to a processing volume of the process chamber to which the remote plasma apparatus is coupled, the remote plasma apparatus may be advantageously configured to have a resonance at a frequency different than the other RF plasma source to prevent interference between the two RF systems.

In embodiments, the gas inlet comprises a plurality of inlet conduits dimensioned and arranged to direct the flow of gas into the cavity in an inflow direction oriented from colinear too opposite an outflow direction of the flow of gas out of the cavity through the gas outlet. In embodiments, the gas inlet comprises a first plurality of inlet conduits dimensioned and arranged to direct the flow of gas into the cavity and a second plurality of inlet gas conduits dimensioned and arranged to direct the flow of gas into a process chamber to which the remote plasma apparatus is attached to, bypassing the cavity.

In embodiments, the remote plasma apparatus further comprises a gas distribution plate covering the gas outlet, the plate comprising a plurality of holes disposed therethrough. In embodiments, the remote plasma apparatus further comprises a ground element located in or proximate to the gas outlet configured to limit or prevent ions from flowing out of the cavity.

In embodiments, a remote plasma apparatus comprises an enclosure comprising a top end, a plurality of sidewalls forming a cavity within, and an open bottom end engageable with a process chamber. The enclosure has an enclosure circumference and an enclosure height. A first conductor comprising a metal sheet is disposed over a first portion of the enclosure in contact with an outer surface of the sidewalls. A dielectric layer comprising a sheet of dielectric material is disposed over an outer surface of the first conductor and the outer surface of the plurality of sidewalls. A second conductor comprising a metal sheet is disposed over a second portion of the enclosure in contact with an outer surface of the dielectric layer. Each of the first conductor and the second conductor independently have a conductor length of less than or equal to about 99% of the enclosure circumference and a conductor height of greater than or equal to about 50% of the enclosure height. The first portion of the enclosure and the second portion of the enclosure are different and overlap by an overlap amount. A gas inlet comprising a first plurality of inlet conduits are dimensioned and arranged to direct a flow of gas into the cavity. A second plurality of inlet gas conduits can be dimensioned and arranged to direct a flow of gas into a process chamber to which the remote plasma apparatus is attached, bypassing the cavity. A gas outlet is configured to flow the gas out of the cavity. The gas outlet can include a gas distribution plate comprising a plurality of holes disposed therethrough. The first conductor, the second conductor, and the dielectric layer are dimensioned and arranged about the enclosure to have a resonance at an RF frequency in a range of about 400 kHz to 10,000 GHZ (e.g., at a frequency provided by an RF source coupled to the remote plasma apparatus). In some of such embodiments, the remote plasma apparatus further comprises one or more capacitors in electrical communication between the first conductor and the second conductor to provide the desired resonance at an RF frequency in a range of about 400 kHz to 10,000 GHz.

In embodiments, a process chamber comprises, a conductive body and a dielectric lid defining a processing volume. The process chamber can further comprise an RF source comprising an RF feed structure for coupling an RF source to one or more inductive coils coaxially disposed proximate the process chamber, configured to inductively couple RF energy into the processing volume. Alternatively, the RF source can be capacitively coupled to the processing chamber, for example via an electrode disposed in the lid, a showerhead, the substrate support, or some other component of the process chamber. The process chamber further comprises at least one remote plasma apparatus comprising an enclosure surrounding a cavity; a first conductor surrounding a first portion of the enclosure, and a second conductor surrounding a second portion of the enclosure. The second conductor is separated from the first conductor by a dielectric layer. A portion of each conductor overlap by an overlap amount. A first gas inlet is provided to flow a gas into the cavity. In some embodiments, a second gas inlet is provided to flow a gas into the processing volume independent of the first gas inlet.

In embodiments, the gas outlet of the remote plasma apparatus is directly mounted to an outer surface of the process chamber, e.g., to the lid, a side or a bottom of the process chamber, such that the gas outlet is located essentially at an entrance to the process chamber. In embodiments, the remote plasma apparatus is mounted proximate to the process chamber such that the gas outlet is located less than or equal to about 30.5 cm from the process chamber. Providing the gas outlet of the remote plasma apparatus in close proximity to the processing volume of the process chamber advantageously limits recombination of radicals that may occur due to longer transit time and distances travelled when the remote plasma apparatus is disposed at further distances from the processing volume.

In embodiments, the remote plasma apparatus further comprises a grounding element proximate to the gas outlet suitable to prevent at least a portion of ions from flowing out of the gas outlet. In embodiments, the gas flow out of the gas outlet comprises radicals produced within the cavity. In embodiments, the first conductor and the second conductor are dimensioned and arranged to prevent parasitic loading of the RF source. In embodiments, at least one of the first conductor and the second conductor comprise at least one hole disposed therethrough and/or a non-linear edge, dimensioned and arranged to reduce or eliminate eddy currents induced into the remote plasma apparatus by the RF source. In embodiments, the first conductor, the second conductor, and the dielectric layer are dimensioned and arranged about the enclosure, and/or one or more capacitors are disposed in electrical communication between the first conductor and the second conductor, such that the remote plasma apparatus has a resonance at an RF frequency in a range of about 400 kHz to 10,000 GHz.

In embodiments, a method of generating a plasma comprising, flowing a gas through a gas inlet of a remote plasma apparatus according to one or more embodiments disclosed herein. The method of generating a plasma may further include the remote plasma apparatus being disposed proximate to an RF source. In embodiments of the method of generating a plasma, the first conductor, the second conductor, and the dielectric layer are dimensioned and arranged about the enclosure to have a resonance at an RF frequency in the cavity sufficient to produce a plasma therein.

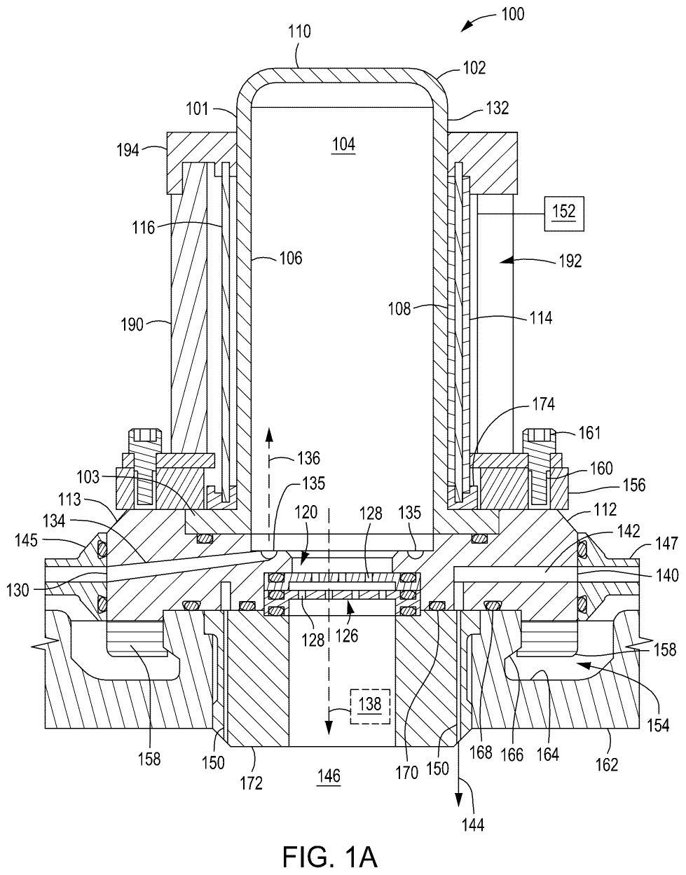

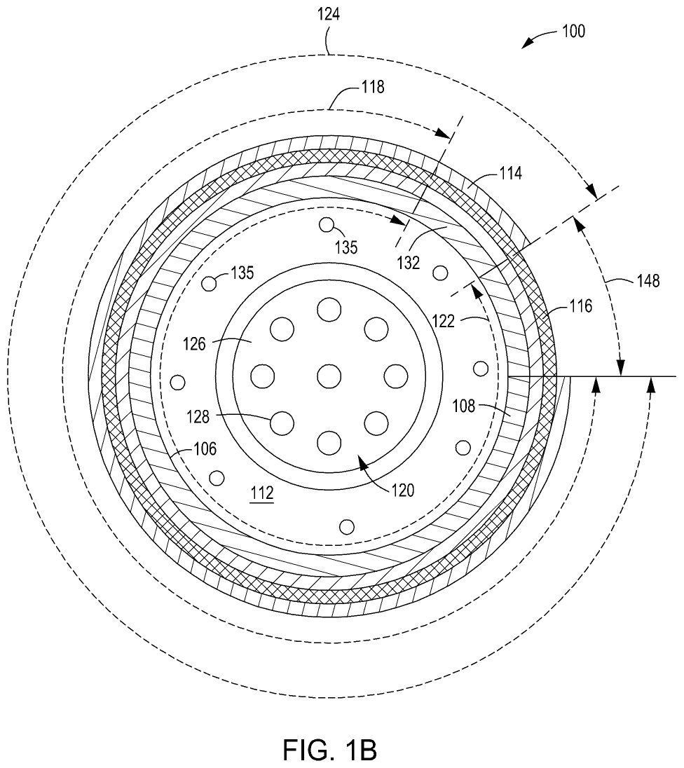

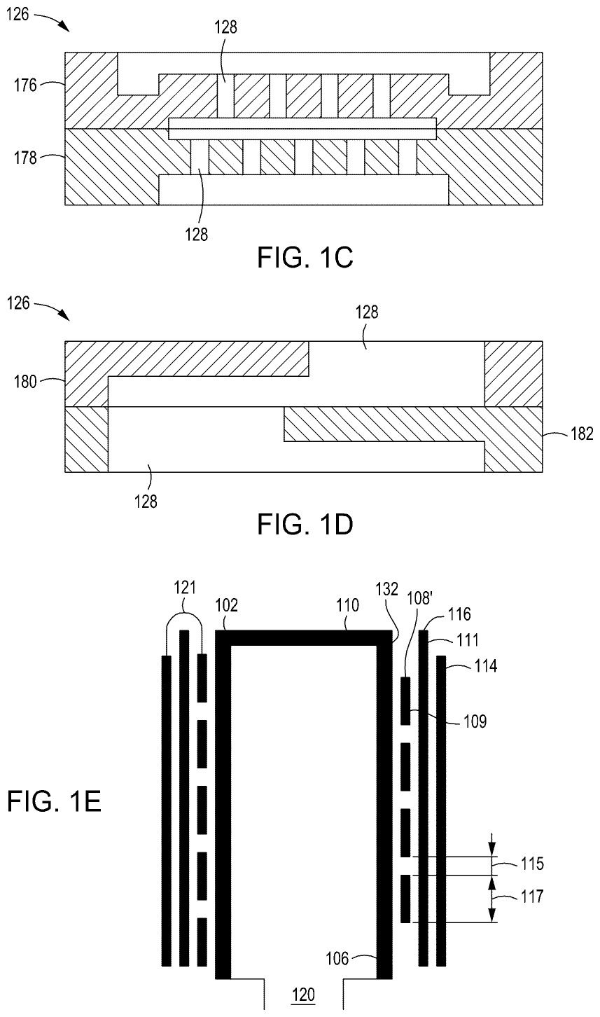

FIG. 1A depicts a side cut-away view of a remote plasma apparatus 100 according to embodiments disclosed herein, comprising an enclosure 102 surrounding a cavity 104 formed within one or more sidewalls 106 of the enclosure 102. The enclosure 102 may be generally suitable for operating at vacuum pressures, for example, such as pressures in the 0.1 mTorr to 100 Torr range, or other pressures as required. In embodiments, a first conductor 108 surrounds a first portion of the enclosure and a second conductor 114 surrounds a second portion of the enclosure. In embodiments, each of the first conductor 108 and the second conductor 114 are circumferentially discontinuous, for example, to avoid formation of eddy currents during use. The second conductor 114 is separated from the first conductor 108 by a dielectric layer 116. For example, the first conductor 108 can be disposed about an outer surface 132 of the enclosure 102, with the dielectric layer 116 (e.g., a tubular dielectric sleeve) can surround the first conductor 108, and the second conductor 114 can be disposed about the dielectric layer 116.

The remote plasma apparatus 100 further comprises one or more first gas inlets 130 comprising one or more inlet conduits 134 dimensioned and arranged or otherwise configured to flow a gas into the cavity 104 via terminal gas inlets 135, and a gas outlet 120 configured to flow the gas out of the cavity 104. Gas lines 145 can be coupled to the one or more first gas inlets 130 to provide the gas to the cavity 104.

The enclosure 102 (or cup 101) and the dielectric layer 116 can be formed of a ceramic, such as alumina, quartz, or the like. The first conductor 108 and the second conductor 114 can be made of a suitable conductive material, such as copper, aluminum, or the like.

For example, in some embodiments, the enclosure 102 can be formed by a cup 101 surrounding the cavity 104 and having a flange 103 disposed about the open end of the cup 101. The cup 101 may sit on a base 113. The base 113 can include a ledge or recess to accept the flange 103. A groove can be formed in at least one of the base 113 or the flange 103 to receive a gasket (such as an o-ring or the like) to facilitate forming a seal between the cup 101 and the base 113. The first conductor 108, the dielectric layer 116, and the second conductor 114 may be disposed about the sidewalls (e.g., sidewalls 106) of the cup 101.

An RF source 152 is coupled to the remote plasma apparatus 100. The RF source 152 can be coupled capacitively or inductively to the remote plasma apparatus 100. For example, an RF signal can be coupled from the RF source 152 to one of the first conductor 108 or the second conductor 114 via a conductor, with the other of the first conductor 108 or the second conductor 114 providing an RF return path to ground. Alternatively, a conductor can be looped around the remote plasma apparatus 100 proximate the first conductor 108 and the second conductor 114 such that RF energy flowing through the conductor is inductively coupled to the remote plasma apparatus 100. The first conductor 108 and the second conductor 114 are configured to have a resonance at or near the frequency of the RF source 152.

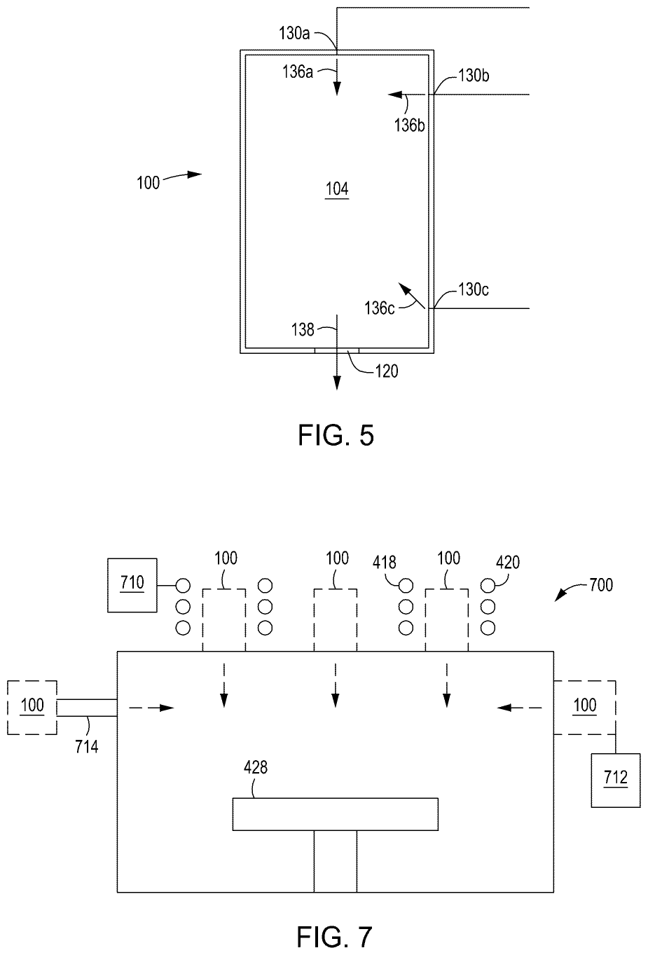

In embodiments, the one or more inlet conduits 134 of the first gas inlet 130 are dimensioned and arranged or otherwise configured to flow gas into the cavity. In some embodiments, the one or more inlet conduits 134 flow gas into the cavity in an inflow direction 136 oriented from colinear to opposite an outflow direction 138 of the flow of gas out of the cavity through the gas outlet 120. Although shown disposed in a bottom end 112 of the enclosure 102, the first gas inlet 130 can alternatively or in combination be disposed in sidewalls or a top end 110 of the enclosure 102 (see, e.g., FIG. 5, discussed below).

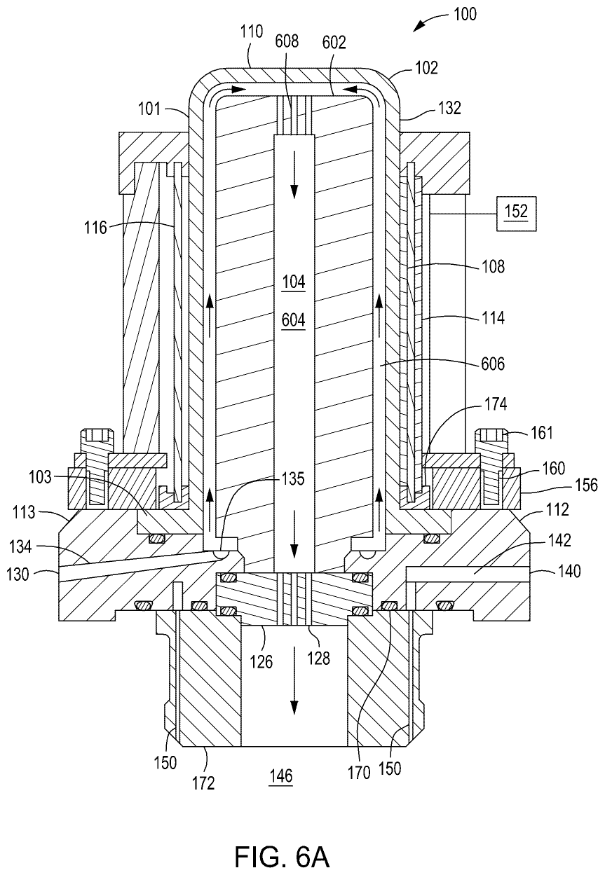

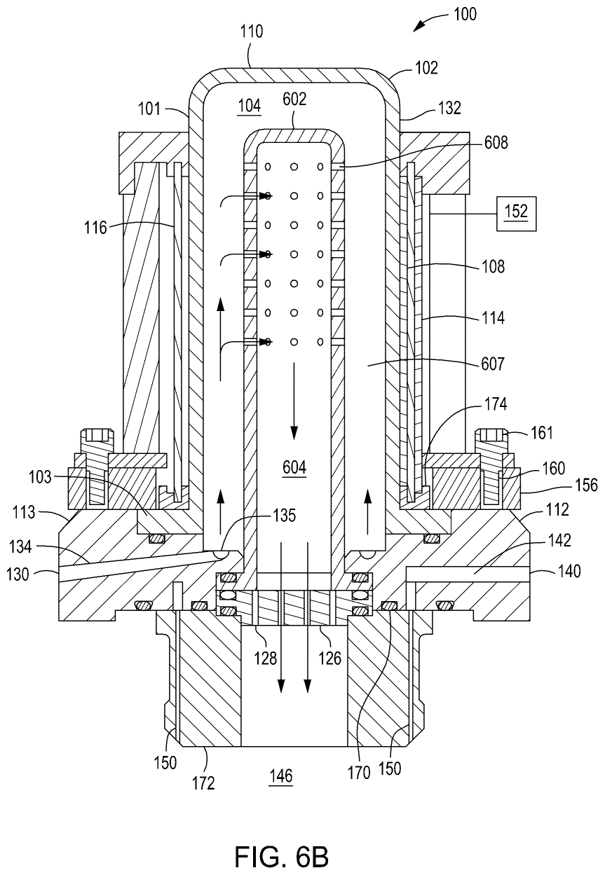

In some embodiments, the remote plasma apparatus 100 can include one or more baffles disposed within the cavity 104 of the enclosure 102 to increase the gas residence time in the plasma volume and thus enhance radical generation. For example, as depicted in FIG. 6A, the remote plasma apparatus 100 includes a baffle 602 disposed in the cavity 104. The baffle 602 can be formed as a tube having an open end adjacent the gas outlet 120 (and the gas distribution plate 126) and an opposite closed end disposed proximate the top of the enclosure 102. In the embodiment shown in FIG. 6A, the baffle 602 can be sized to form a larger plasma volume 604 surrounded by the baffle 602 and a smaller gap 606 that is small enough to prevent plasma formation within the gap 606 based on the processing conditions (e.g., pressure, RF frequency, RF power applied, and the like). The closed end of the tube includes one or more through holes 608. As indicated by the arrows in FIG. 6A, gas provided through the gas inlets 135 flows around the outside of the baffle 602 along the gap 606 to the top of the cavity 104 and then passes through the one or more through holes 608 and into the plasma volume 604 where the plasma can dissociate the gas to form radicals. The gas then flows through the gas outlet 120 (e.g., through the gas distribution plate 126) and into the processing volume 146 of the process chamber to which the remote plasma apparatus 100 is attached.

In some embodiments, and as depicted in FIG. 6B, the remote plasma apparatus 100 includes the baffle 602 disposed in the cavity 104. The baffle 602 can be formed as a tube having an open end adjacent the gas outlet 120 (and the gas distribution plate 126) and an opposite closed end disposed proximate the top of the enclosure 102. In the embodiment shown in FIG. 6B, the baffle 602 can be sized to form an inner plasma volume 604 surrounded by the baffle 602 and an outer plasma volume 607 disposed between the baffle 602 and the inner sidewalls of the enclosure 102. Plasma can be formed in both the inner plasma volume 604 as well as in the outer plasma volume 607. In embodiments, the plasma in the outer plasma volume 607 can be a stronger plasma (e.g., the main or primary plasma), and the plasma formed in the inner plasma volume 604 can be a weaker plasma. A plurality of through holes 608 are formed through the baffle 602 proximate the closed end of the tube. For example the through holes can be formed proximate an end of the baffle 602 opposite the open end (e.g. along the sidewall of the baffle 602). Alternatively or in combination, through holes 608 can be formed through the closed end of the tube. As indicated by the arrows in FIG. 6A, gas provided through the gas inlets 135 flows around the outside of the baffle 602 along the outer plasma volume 607 where the plasma can dissociate the gas to form radicals to the top of the cavity 104 and then passes through the plurality of through holes 608 and into the inner plasma volume 604 where the plasma can further dissociate the gas to form radicals. The gas then flows through the gas outlet 120 (e.g., through the gas distribution plate 126) and into the processing volume 146 of the process chamber to which the remote plasma apparatus 100 is attached.

As depicted in FIG. 1A, in embodiments, the remote plasma apparatus 100 can further include a clamping feature 154, which can include an upper clamp element 156 and a lower clamp element 158. The clamping feature 154 can also include one or more attachment holes 160 which may include a threaded member or other type of fastener 161 to secure the remote plasma apparatus 100 to the process chamber wall or lid 162. As depicted in FIG. 1A, the clamping feature 154 may engage the process chamber wall or lid 162 via a corresponding channel 164 having an engagement surface 166 which engages the lower clamp element 158.

As depicted in FIG. 1A, in embodiments, the remote plasma apparatus 100 can further include a one or more sealing gaskets disposed into the enclosure 102. For example, one or more sealing gaskets 170 (e.g., o-rings or the like) can be provided between the bottom end 112 of the enclosure 102 and the nozzle 172. Alternatively or in combination, one or more sealing gaskets 168 (e.g., o-rings or the like) can be provided between the bottom end 112 of the enclosure 102 and a corresponding chamber component, such as the chamber wall or lid 162 of a process chamber to which the remote plasma apparatus 100 is attached. As depicted in FIG. 1A, in embodiments, the gas outlet 120 of the remote plasma apparatus 100 can be coupled to a nozzle 172 disposed adjacent to the gas outlet 120. The nozzle includes a central opening fluidly coupled to the cavity 104 to facilitate flowing the gas in the outflow direction 138 from the cavity 104 into the processing volume 146 of the process chamber to which the remote plasma apparatus 100 is attached.

As depicted in FIG. 1A, in embodiments, the remote plasma apparatus 100 can further include an insulator ring 174 disposed between the upper clamp element 156 and a lower edge of the first conductor 108 and the second conductor 114. In some embodiments, the insulator ring 174 can include cutouts or recesses along the upper surface thereof to facilitate positioning and alignment of one or more of the first conductor 108, the dielectric layer 116, or the second conductor 114. In some embodiments, a shield can be provided to substantially cover the conductive components of the remote plasma apparatus 100. For example, as depicted in FIG. 1A, a shield wall 190 can be provided to surround or substantially surround the second conductor 114. An opening 192 may be provided in the shield wall 190, for example, for observation of glow discharge during use of the remote plasma apparatus 100. In some embodiments, a cap 194 can be disposed over the shield wall 190. The cap 194 can be fastened to the shield wall 190 in any suitable manner, such as by bolting. In some embodiments, the cap 194 can include cutouts or recesses along the bottom surface thereof to facilitate positioning and alignment of one or more of the first conductor 108, the dielectric layer 116, the second conductor 114, or the shield wall 190.

FIG. 1B depicts a schematic, cross-sectional top view of the remote plasma apparatus 100. As depicted in FIG. 1B, in embodiments, the first portion 122 of the outer surface 132 of the enclosure 102 is surrounded by the first conductor 108. As is also depicted in FIG. 1B, in embodiments, the second portion 124 of the outer surface 132 of enclosure 102 is surrounded by the second conductor 114. As is also depicted in FIG. 1B, in embodiments, the first portion 122 and the second portion 124 of the outer surface 132 of enclosure 102 overlap one-another by an overlap amount 118. As is also depicted in FIG. 1B, in embodiments, the second conductor 114 is movable (e.g., via rotation indicated by dotted arrow 148) with respect to the first conductor to change the overlap amount.

In embodiments, the remote plasma apparatus 100 further comprises a gas distribution plate 126 covering or disposed in-line with the gas outlet 120. The gas distribution plate 126 includes a plurality of holes 128 disposed therethrough to facilitate passage and distribution of gas flowing from the cavity 104 to the processing volume 146. The gas distribution plate can advantageously limit the number of ions leaving the cavity 104 of the remote plasma apparatus 100. For example, the gas distribution plate 126 is advantageously dimensioned and arranged to reduce or prevent ions from flowing out of the gas outlet, such that the gas flow out of the gas outlet comprises a greater percentage of radicals produced within the cavity.

As depicted in FIG. 1A, in embodiments, the gas distribution plate 126 can include a plurality of holes 128 disposed therethrough, arranged in two or more plates. such that the holes 128 are not aligned and no line-of-sight pathway exists through the gas distribution plate 126. Similarly, and as depicted in FIG. 1C, in embodiments, the gas distribution plate 126 can include a plurality of holes 128 disposed therethrough, arranged in two or more plates, e.g., upper plate 176 and lower plate 178 such that the holes 128 are not aligned and no line-of-sight pathway exists through the gas distribution plate 126. Such a configuration can advantageously further limit the number of ions leaving the cavity 104 of the remote plasma apparatus 100 due to the more convoluted flow pathway.

As depicted in FIG. 1D, in embodiments, a gas distribution plate 126 comprises a plurality of holes 128 disposed therethrough and is formed from two or more segments. As depicted in FIG. 1D, the gas distribution plate 126 is formed from a first grounding segment 180 and second grounding segment 182 forming a pair of D-shaped (or semi-circular) structures. In embodiments, the first grounding segment 180 and/or the second grounding segment 182 may be electrically floating or connected to ground. The embodiment depicted in FIG. 1C can also be electrically conductive and be electrically floating or coupled to ground.

Alternatively, and as depicted in FIG. 6A and FIG. 6B, in embodiments, the gas distribution plate 126 can include a single plate having the plurality of holes 128 disposed therethrough. In some embodiments, the gas distribution plate 126 can be formed of a dielectric material. In some embodiments, the gas distribution plate 126 (whether a single plate or two or more plates) can be formed of an electrically conductive materials and can be electrically grounded or floating to facilitate control over the amount of ions leaving the cavity 104.

In embodiments, the first conductor surrounding a first portion of the enclosure comprises a spiral having a plurality of turns disposed about the first portion of the enclosure. As depicted in FIG. 1E, in embodiments the first conductor is a spiral first conductor 108′, is oriented in spiral, radially disposed about a center of the enclosure 102, and disposed about the outer surface 132 of the enclosure 102. The dielectric layer 116 is formed into a cylinder and disposed over an outer surface 109 of the spiral first conductor 108′. The second conductor 114 has a general C-shape as discussed above and is disposed over an outer surface 111 of the dielectric layer 116.

In embodiments, the spiral first conductor 108′ is formed from a flat sheet, having a width 117 of the conductor which forms the spiral first conductor 108′. The turns of the spiral are oriented with a spacing 115 between the spirals such that the first is disposed over a first portion of the enclosure. The area of the first portion covered by the spiral first conductor 108′ may be varied by the width of the conductor, the spacing between the turns of the conductor, and the length and/or the number of turns of the conductor about the enclosure. In embodiments, the spiral first conductor 108′ and the second conductor 114 are dimensioned and arranged to produce a resonance at a desired frequency. In embodiments, the spiral first conductor 108′ may be in direct electrical connection with the second conductor 114 at one location, or in some embodiments in a plurality of locations, for example, as depicted by conductor 121 coupling the top end of the spiral first conductor 108′ to a point along an upper portion of the second conductor 114.

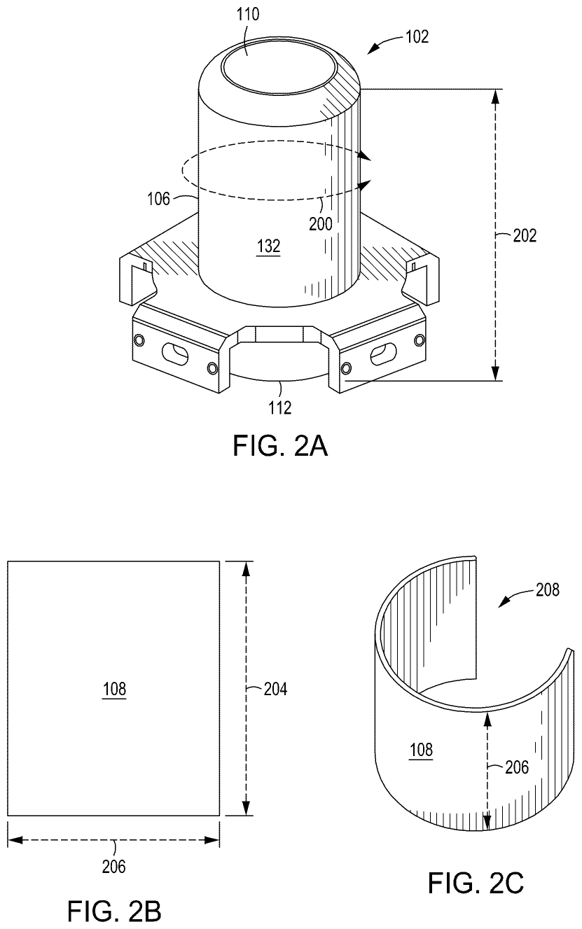

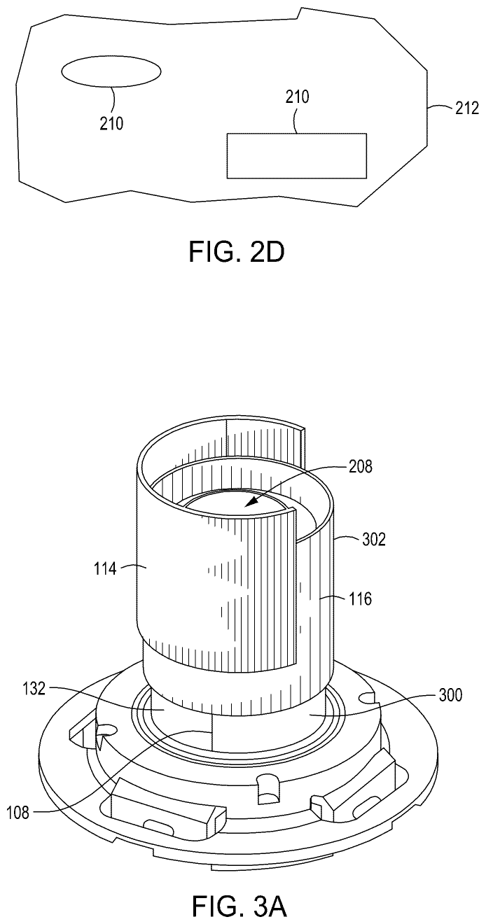

FIG. 2A depicts the enclosure 102 having the top end 110 located opposite the bottom end 112, and a sidewall 106, and having an enclosure circumference 200 and an enclosure height 202 wherein the cavity 104 is formed within the plurality of sidewalls 106 and between the top end 110 and the bottom end 112 (see FIG. 1A).

FIG. 2B depicts the first conductor 108 as a flat metal sheet having a conductor length 204 of less than or equal to about 99%, or less than or equal to about 90%, or less than or equal to about 80% of the enclosure circumference 200, and a conductor height 206 of greater than or equal to about 50%, or greater than or equal to about 60%, or greater than or equal to about 70%, or essentially equal to the enclosure height 202. As depicted in FIG. 2C, the flat metal sheet of the first conductor 108 is formed into a C-shaped metal sheet 208, dimensioned and arranged to fit over the outer surface 132 of the enclosure 102. By forming the flat metal sheet into a C-shaped structure, the conductor length 204 of the metal sheet is oriented about or along the enclosure circumference 200.

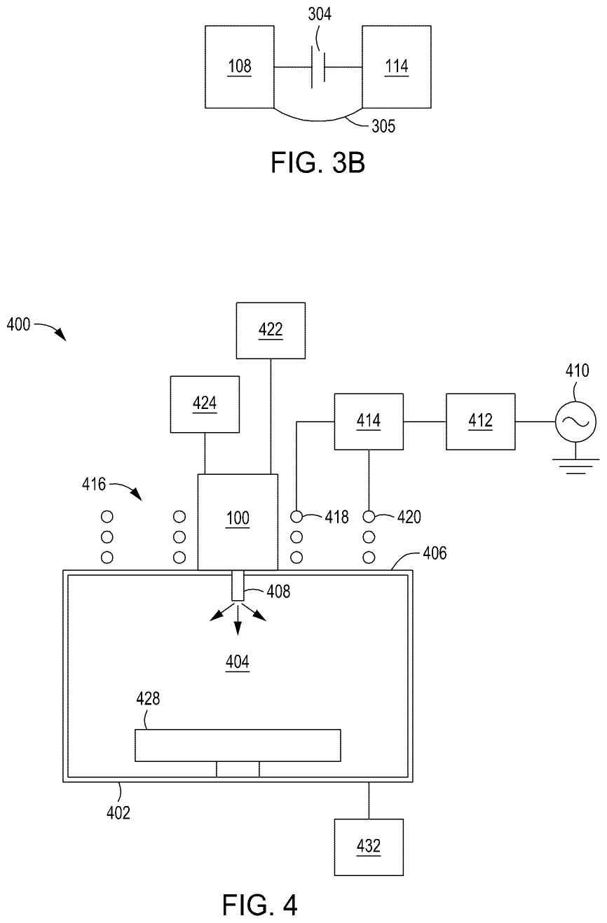

The second conductor 114 can be formed in the same way, with the proviso of being dimensioned and arranged to fit over an outer surface of the dielectric layer 116 (see FIG. 3A, 302), disposed between the first conductor 108 and the second conductor 114. In embodiments, the dimensions e.g., the conductor length 204 and the conductor height 206, a surface area, a thickness, and/or the like, of the first conductor 108 and the second conductor 114 are essentially identical. In embodiments, the first conductor 108 and the second conductor 114 have at least one different dimension.

The first conductor 108 and the second conductor 114 can be formed from any suitable conductive material. Suitable examples include copper, aluminum, ferrous alloys, and/or the like. In embodiments, the first conductor 108 and the second conductor 114 are formed from the same material. In embodiments, the first conductor 108 and the second conductor 114 are formed from different materials.

As depicted in FIG. 2D, in embodiments, at least one of the first conductor 108 and the second conductor 114 comprises at least one hole 210 disposed therethrough and/or a non-linear edge or side 212, dimensioned and arranged to reduce or eliminate eddy currents induced into the remote plasma apparatus by an external RF source.

As depicted in FIG. 3A, the first conductor 108 is disposed over an outer surface 132 of the enclosure 102. A dielectric layer 116, which can either comprise a sheet of dielectric material (similar in shape as the first conductor depicted in FIG. 2B) or which may be one continuous layer e.g., formed into a cylinder, is disposed over an outer surface 300 of the first conductor 108, and the outer surface 132 of the enclosure; and the second conductor 114 is disposed over an outer surface 302 of the dielectric layer 116.

In embodiments, the dielectric layer 116 can be formed from an air gap. In other embodiments, the dielectric layer 116 comprises a dielectric material. Suitable dielectric materials include a ceramic, such as alumina, quartz, or the like.

In embodiments, a thickness of the dielectric layer 116 is greater than or equal to about 0.1 mm, or greater than or equal to about 0.5 mm, or greater than or equal to about 1 mm, or greater than or equal to about 3 mm, and less than or equal to about 10 mm, or less than or equal to about 8 mm, or less than or equal to about 7 mm, or less than or equal to about 5 mm.

In embodiments, the first conductor 108, the second conductor 114, and the dielectric layer 116 are dimensioned and arranged about the enclosure 102 to have a resonance at an RF frequency in a range of greater than or equal to about 400 kHz and less than or equal to about 10,000 GHz, which in embodiments may be greater than or equal to about 1 MHZ, or greater than or equal to about 3 MHZ, or greater than or equal to about 10 MHz, and less than or equal to about 5000 GHz, or less than or equal to about 1000 GHz, or less than or equal to about 5 GHZ, or less than or equal to about 200 MHz.

As depicted schematically in FIG. 3B, in embodiments, a portion of the first conductor 108 may be in direct electrical connection 305 with the second conductor 114, for example by a conductor coupled to each of the first conductor 108 and the second conductor 114. Alternatively or in combination, the remote plasma apparatus 100 can comprise or more capacitors 304 in electrical communication between the first conductor 108 and the second conductor 114, which may be in series and/or in parallel, such that the remote plasma apparatus 100 has a resonance at an RF frequency within a range from about 400 kHz to 10,000 GHz (e.g., a resonance at an RF frequency provided by the RF source 152).

FIG. 4 depicts a schematic side view of a substrate processing chamber 400 having a remote plasma apparatus 100 suitable for use herein. The processing chamber 400 can be utilized alone or as a processing module of an integrated semiconductor substrate processing system (e.g., a cluster tool). Examples of suitable processing chambers that may advantageously benefit from modification in accordance with embodiments of the present disclosure include plasma processing chambers, such as capacitively or inductively coupled plasma processing chambers. Exemplary plasma processing chambers includes etch reactors, CVD reactors, substrate plasma treatment reactors, and the like. Although described as used with a plasma processing chamber having a separate plasma source, remote plasma apparatus in accordance with the teachings herein can also be used in processing chambers that do not have any additional plasma capabilities.

The processing chamber 400 generally includes a chamber body 402 and a lid 406 that together define a processing volume 404. A substrate support 428 is disposed within the processing volume. The processing chamber 400 can optionally include an inductive or capacitive plasma source. In the embodiment depicted in FIG. 4, an inductive plasma source is provided, including one or more electrodes (e.g., conductive coils 416) disposed proximate the lid 406. In such an embodiment, the lid 406 is dielectric and the chamber body is conductive. The one or more conductive coils 416 can be disposed above the dielectric lid 406 and are configured to inductively couple RF energy into the processing volume 404.

In the embodiment depicted in FIG. 4A, the inductive plasma source includes an RF feed structure for coupling an RF source 410 (e.g., a second RF source) to the one or more conductive coils 416, e.g., a first conductive coil 418 and a second conductive coil 420. The one or more conductive coils are coaxially disposed proximate the processing chamber 400 (for example, above the dielectric lid 406 of the processing chamber 400) and are configured to inductively couple RF energy into the processing volume 404 to form or control a plasma from process gases provided within the processing volume 404 via a gas source 422 coupled to a gas inlet. As depicted in FIG. 1A, the gas inlet can be at least one of the first gas inlet 130 and the second gas inlet 140 (see FIG. 1A) of the remote plasma apparatus 100. Alternatively or in combination, the gas source 422 can be coupled to the processing volume 404 at other locations. The gas outlet 120 of the remote plasma apparatus 100 may function as, or be in direct fluid communication with, a showerhead or nozzle 408 (which, for example, can be the nozzle 172 depicted in FIG. 1A).

The RF source 410 is coupled to the RF feed structure via a match network 412. A power divider 414 may be provided to adjust the RF power respectively delivered to the first conductive coil 418 and the second conductive coil 420. The power divider 414 may be coupled between the match network 412 and the RF feed structure or may be a part of the match network 412. The RF source 410 may be capable of producing sufficient power at a tunable frequency within a range from about 400 kHz to about 10,000 GHz, or from about 400 kHz to about 13.56 MHz, although other frequencies and powers may be provided as desired for particular applications.

A remote plasma apparatus (e.g., the remote plasma apparatus 100) is coupled to the chamber body 402 or the lid 406. The gas outlet of the remote plasma apparatus can be directly mounted to an outer surface of the process chamber, e.g., to the lid 406, a side or a bottom of the chamber body 402, such that the gas outlet is located essentially at an entrance to the processing volume 404. For example, the remote plasma apparatus is mounted to the process chamber such that the gas outlet is located less than or equal to about 30.5 cm from the process chamber. The remote plasma apparatus is coupled to an RF source 424 in any of the ways discussed above. The remote plasma apparatus has a resonance at a frequency proximate to the frequency of the RF source 424. In embodiments, the RF source 424 has a different frequency than the RF source 410, advantageously limiting a parasitic load on the RF source 410 from the remote plasma apparatus 100. In embodiments, the RF frequency of the RF source 424 is higher than the RF frequency of the RF source 410. In embodiments, the RF frequency of the RF source 424 is lower than the RF frequency of the RF source 410.

FIG. 5 is a block diagram of the remote plasma apparatus 100 depicting various locations and orientations of one or more first gas inlets 130a, 130b, and 130c. Each of the first gas inlets 130a, 130b, and 130c can include a corresponding plurality of inlet conduits (see FIG. 1A). Each of the first gas inlets 130a, 130b, and 130c produce a corresponding inflow direction 136a, 136b, and 136c relative to the outflow direction 138 through the gas outlet 120.

In embodiments, in addition to the one or more first gas inlets 130 to direct the flow of gas into the cavity 104, the remote plasma apparatus 100 can comprise one or more second gas inlets 140 comprising one or more second inlet gas conduits 142 dimensioned and arranged to direct the flow of gas 144 through a corresponding one or more second gas outlets 150 into the processing volume 146, bypassing the cavity 104. Gas lines 147 can be coupled to the one or more second gas inlets 140 to provide the gas to the processing volume 146. For example, and as depicted in FIG. 1A, one or more second inlet gas conduits 142 can be disposed in the bottom end 112 of the enclosure 102 and can direct gas away from the cavity 104 and toward the nozzle 172. The nozzle 172 can include the one or more second gas outlets 150 disposed through the nozzle 172, for example, adjacent the central opening of the nozzle 172. In embodiments where a plurality of second gas outlets 150 are provided, the plurality of second gas outlets 150 can be symmetrically arranged about a central axis of the central opening of the nozzle 172.

FIG. 7 depicts a portion of a process chamber 700 showing locations where a remote plasma apparatus 100 can be mounted. As depicted in FIG. 7, remote plasma apparatus 100 may be directly engaged with a surface of the process chamber 700. As depicted in FIG. 7, in embodiments, the process chamber 700 may comprise one or a plurality of remote plasma apparatus 100, which may be disposed on a lid or top of the process chamber, on a side of the process chamber, or on a bottom of the process chamber. In embodiments, the plurality of remote plasma apparatus 100 may be distributed symmetrically, or non-symmetrically about one or more outer surfaces of the process chamber. In embodiments, each of the remote plasma apparatus 100 may be independently powered by an RF source 712. Optionally, an additional plasma source can be provided, such as conductive coils 418, 420 coupled to RF source 710. In embodiments, the remote plasma apparatus 100 can be utilized as a point of use plasma source, and/or a point of use radical source for substrate processing. Accordingly, in embodiments, the gas outlet 120 of the remote plasma apparatus 100 may be engaged with the process chamber 700 via a conduit 714, in which the gas outlet is located less than or equal to about 30.5 cm, or less than or equal to about 20 cm, or less than or equal to about 10 cm, or less than or equal to about 5 cm from the process chamber.

In embodiments, a process chamber comprises a first RF source coupled to the remote plasma source. Optionally, a second RF source is coupled to one or more electrodes disposed proximate the chamber and configured to form a plasma within the processing volume, independent of the first RF source. In embodiments, the second RF source is inductively coupled to one or more conductive coils disposed atop the process chamber. In embodiments, the first RF source is directly or inductively coupled to the remote plasma apparatus. In embodiments, the first RF source is coupled to the remote plasma apparatus through one or more capacitors disposed between the first RF source and the remote plasma apparatus. In embodiments, one of the conductors of the remote plasma apparatus is connected to ground through a capacitor. The second RF source has a different RF frequency than that of the first RF source. In embodiments, the RF frequency of the second RF source is higher than the RF frequency of the first RF source. In embodiments, the RF frequency of the second RF source is lower than the RF frequency of the first RF source.

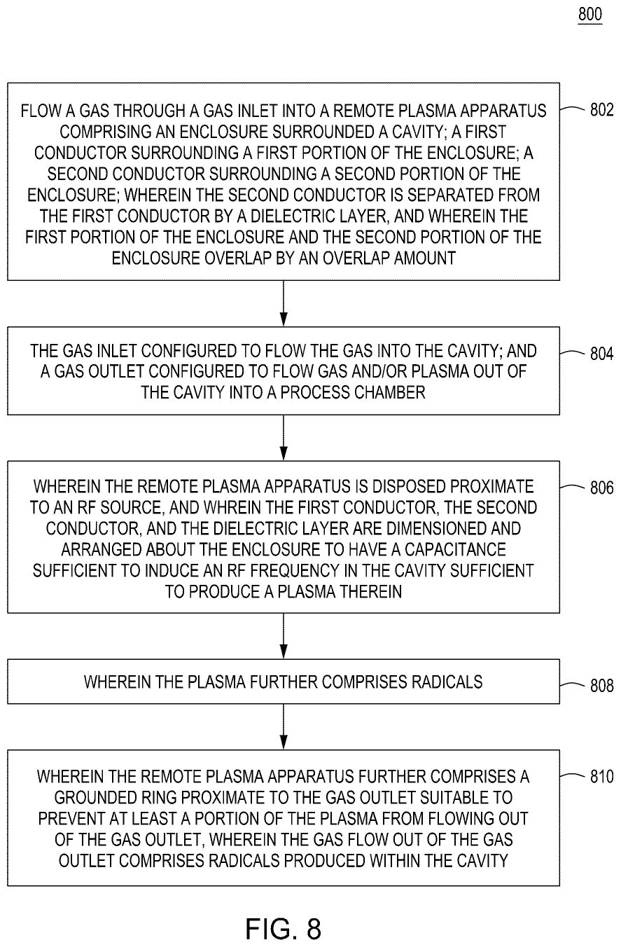

FIG. 8 is a flowchart depicting a method of generating plasma according to embodiments disclosed herein. For purposes herein, a method or process, one or more process blocks of FIG. 8 may be performed by one or more substrate processing systems. The substrate processing systems can be controlled by a controller, which can include a memory or computer readable medium having the one or more process blocks of process 800 stored therein. When executed by the controller, the one or more substrate processing systems are controlled to perform one or more blocks of the process 800 as described herein. According to an example, one or more process blocks of FIG. 8 may be performed by remote plasma apparatus 100 according to an example of the present disclosure.

As depicted in FIG. 8, process 800 may include flowing a gas through a gas inlet into a remote plasma apparatus having an enclosure surrounded a cavity; a first conductor surrounding a first portion of the enclosure; a second conductor surrounding a second portion of the enclosure; where the second conductor is separated from the first conductor by a dielectric layer, and where the first portion of the enclosure and the second portion of the enclosure overlap by an overlap amount (block 802).

For example, remote plasma apparatus 100 may flow a gas comprising one or more radical forming compounds (e.g., process gases) which form radicals within the cavity and which then flow out through the gas outlet and into the process chamber, for example, for processing a substrate disposed therein.

As also depicted in FIG. 8 process 800 may include the gas inlet configured to flow the gas into the cavity; and a gas outlet configured to flow gas and/or plasma out of the cavity into a process chamber (block 804). As further depicted in FIG. 8, process 800 may include where the remote plasma apparatus is disposed proximate to an RF source, and where the first conductor, the second conductor, and the dielectric layer are dimensioned and arranged about the enclosure to have a resonance at an RF frequency in the cavity sufficient to produce a plasma therein (block 806).

In embodiments, the plasma further comprises radicals (block 808) and in embodiments, the remote plasma apparatus further comprises a grounding element or other structure proximate to the gas outlet suitable to prevent at least a portion of ions from flowing out of the gas outlet, wherein the gas flow out of the gas outlet comprises radicals produced within the cavity (block 810).

Although FIG. 8 depicts example blocks of process 800, in some implementations, process 800 may include additional blocks, fewer blocks, different blocks, or differently arranged blocks than those depicted in FIG. 8. Additionally, or alternatively, two or more of the blocks of process 800 may be performed in parallel.

While the foregoing is directed to embodiments of the present disclosure, other and further embodiments of the disclosure may be devised without departing from the basic scope thereof.

1. A remote plasma apparatus, comprising:
an enclosure surrounding a cavity;
a first conductor surrounding a first portion of the enclosure;
a second conductor surrounding a second portion of the enclosure, wherein the first portion of the enclosure and the second portion of the enclosure overlap by an overlap amount, and wherein each of the first conductor and the second conductor are circumferentially discontinuous;
a dielectric layer disposed between and separating the first conductor and the second conductor;
a gas inlet configured to flow a gas into the cavity; and
a gas outlet disposed in a bottom of the enclosure and configured to flow the gas out of the cavity.

2. The remote plasma apparatus of claim 1, wherein the first portion and the second portion are different.

3. The remote plasma apparatus of claim 1, wherein a surface area of the first conductor is essentially equal to a surface area of the second conductor.

4. The remote plasma apparatus of claim 1, wherein the enclosure comprises a top and a plurality of sidewalls having an enclosure circumference and an enclosure height such that the cavity is formed within the plurality of sidewalls and the top, and wherein the first conductor and the second conductor are each C-shaped metal sheets, each having a conductor length of less than or equal to about 99% of the enclosure circumference, and a conductor height of greater than or equal to about 50% of the enclosure height.

5. The remote plasma apparatus of claim 1, wherein the first conductor is a spiral comprising a plurality of turns disposed about the first portion of the enclosure.

6. The remote plasma apparatus of claim 1, wherein the first conductor and the second conductor are electrically connected at one location.

7. The remote plasma apparatus of claim 1, wherein the first conductor comprises a metal sheet disposed over an outer surface of the enclosure, wherein the dielectric layer comprises a sheet of dielectric material disposed over an outer surface of the first conductor and the outer surface of the enclosure, and wherein the second conductor is a metal sheet disposed over an outer surface of the dielectric layer.

8. The remote plasma apparatus of claim 7, wherein at least one of the first conductor and the second conductor comprises at least one hole disposed therethrough and/or a non-linear edge, dimensioned and arranged to reduce or eliminate eddy currents induced into the remote plasma apparatus during use.

9. The remote plasma apparatus of claim 1, wherein the first conductor, the second conductor, and the dielectric layer are dimensioned and arranged about the enclosure to have a resonance at an RF frequency within a range of about 400 kHz to 10,000 GHz.

10. The remote plasma apparatus of claim 9, further comprising one or more capacitors in electrical communication between the first conductor and the second conductor such that the remote plasma apparatus has a resonance at an RF frequency within a range of about 400 kHz to 10,000 GHz.

11. The remote plasma apparatus of claim 1, wherein the second conductor is movable with respect to the first conductor to change the overlap amount.

12. The remote plasma apparatus of claim 1, wherein the gas inlet comprises a plurality of inlet conduits dimensioned and arranged to direct the flow of gas into the cavity in an inflow direction oriented from colinear too opposite an outflow direction of the flow of gas out of the cavity through the gas outlet.

13. The remote plasma apparatus of claim 1, wherein the gas inlet comprises a first plurality of inlet conduits dimensioned and arranged to direct the flow of gas into the cavity and a second plurality of inlet gas conduits dimensioned and arranged to direct the flow of gas into a process chamber to which the remote plasma apparatus is attached to, bypassing the cavity.

14. The remote plasma apparatus of claim 1, further comprising a gas distribution plate covering the gas outlet, the gas distribution plate comprising a plurality of holes disposed therethrough.

15. The remote plasma apparatus of claim 14, wherein the gas distribution plate is coupled to ground.

16. A remote plasma apparatus, comprising:
an enclosure comprising a top end, one or more sidewalls forming a cavity within, and an open bottom end engageable with a process chamber, the enclosure having an enclosure circumference and an enclosure height;
a first conductor comprising a metal sheet disposed over a first portion of the enclosure in contact with an outer surface of the one or more sidewalls;
a dielectric layer comprising a sheet of dielectric material disposed over an outer surface of the first conductor and the outer surface of the one or more sidewalls;
a second conductor comprising a metal sheet disposed over a second portion of the enclosure in contact with an outer surface of the dielectric layer, wherein each of the first conductor and the second conductor independently have a conductor length of less than or equal to about 99% of the enclosure circumference and a conductor height of greater than or equal to about 50% of the enclosure height, wherein the first portion of the enclosure and the second portion of the enclosure are different and overlap by an overlap amount, and wherein the first conductor, the second conductor, and the dielectric layer are dimensioned and arranged about the enclosure to have a resonance at an RF frequency within a range of about 400 kHz to 10,000 GHz;
a gas inlet comprising a first plurality of inlet conduits dimensioned and arranged to direct a flow of gas into the cavity, and a second plurality of inlet gas conduits dimensioned and arranged to direct the flow of gas into a process chamber to which the remote plasma apparatus is attached to, bypassing the cavity; and
a gas outlet disposed in a bottom of the enclosure and configured to flow the gas out of the cavity, wherein the gas outlet includes a gas distribution plate comprising a plurality of holes disposed therethrough.

17. The remote plasma apparatus of claim 16, further comprising one or more capacitors in electrical communication between the first conductor and the second conductor such that the remote plasma apparatus has a resonance at an RF frequency within a range of about 400 kHz to 10,000 GHz.

18. A plasma processing chamber, comprising:
a chamber enclosing a processing volume;
a substrate support configured to support a substrate in the processing volume during use;
a first RF source configured to provide RF energy at a frequency; and
a remote plasma apparatus coupled to the chamber and to the first RF source, the remote plasma apparatus comprising:
an enclosure surrounding a cavity;
a first gas inlet configured to flow a gas into the cavity;
a gas outlet disposed in a bottom of the enclosure and configured to flow the gas out of the cavity and into the processing volume;
a first conductor surrounding a first portion of the enclosure;
a dielectric layer disposed over the first conductor; and
a second conductor surrounding a second portion of the enclosure,
wherein the first portion of the enclosure and the second portion of the enclosure overlap by an overlap amount, and wherein the first conductor, dielectric layer, and the second conductor at least partially form a capacitor having a resonance proximate the frequency to form an electromagnetic field within the enclosure suitable to form radicals from the gas, when disposed within the enclosure.

19. The plasma processing chamber of claim 18, wherein the gas outlet of the remote plasma apparatus is directly mounted to a lid, a side, or a bottom of the chamber, such that the gas outlet is located less than or equal to about 30.5 cm from the chamber.

20. The plasma processing chamber of claim 18, further comprising:
one or more electrodes; and
a second RF source coupled to the one or more electrodes, wherein the one or more electrodes and second RF source are configured to generate a plasma within the processing volume of the chamber, and wherein the second RF source has a frequency that is different than that of the first RF source.
